(19) United States
(12) Patent Application Publication
(10) Pub. No.: US 2008/0084178 A1
(43) Pub. Date: Apr. 10, 2008

(54) SOLAR POWER SUPPLY WITH MONITORING AND COMMUNICATIONS

(76) Inventors: Raymond P. Dowd, San Mateo, CA (US); Laura E. Linser, San Mateo, CA (US)

Correspondence Address: TECHNOLOGY & INTELLECTUAL PROPERTY;STRATEGIES GROUP PC (dba TIPS GROUP), P. O. BOX 1639, LOS ALTOS, CA, 94023-1639, US

(21) Appl. No.: 11/764,804

(22) Filed: Jun. 18, 2007

Related U.S. Application Data
(60) Provisional application No. 60/805,089, filed on Jun. 18, 2006.

(51) Int. Cl. H02J 7/35; H01L 31/055; H01M 10/44; H02J 7/00

(52) U.S. Cl. 320/101; 307/80

(57) ABSTRACT

In various embodiments, an apparatus, method and system for a solar power supply with monitoring and communications is provided. In one embodiment, an apparatus is provided. The apparatus includes a power source. The apparatus further includes a power regulation module coupled to the power source. The apparatus also includes a battery coupled to the power regulation module. The apparatus includes a communications module coupled to the power regulation module.

### CLAIM OF PRIORITY

This application claims priority to U.S. Provisional Patent Application No. 60/805,089, entitled “SOLAR POWER SUPPLY WITH MONITORING AND COMMUNICATIONS” and filed on Jun. 18, 2006, which is hereby incorporated herein by reference.

### BACKGROUND

Power supplies for all sorts of components and systems have traditionally come in one of three forms. Networked power supply, through the electricity grid in the United States for example, is a common approach—allowing one to simply plug a cord from a component into the wall and have power. Battery power supply, using a built-in or external battery, is also a common approach, and often avoids complex circuitry necessary to transform alternating current into direct current. Generators, powered by fossil fuels for example, are the third common form of power supply, typically used when the electricity grid is not accessible and batteries are unlikely to provide the amount of power necessary. Each of these power supplies can also be mixed and matched, as one sees in use of battery backup power supplies in a computer system, or fail-over generator systems for buildings with critical functions such as hospitals.

Each of these systems generally does not take advantage of one technological development that is beginning to bear fruit commercially. Solar power systems are becoming more robust, commercially feasible, and generally more available. With generators using fossil fuels locally and an electricity grid generating power through use of fossil fuels, any form of power delivery previously discussed requires use of an essentially non-renewable resource. At some scale, hydroelectric power and wind-power may also be used, but this typically applies either to the electrical grid, or to isolated instances where natural and geographical configurations happen to allow for the possibility.

Solar power systems allow for delivery of electrical power in almost any location, without requiring access to an electrical grid, or current use of fossil fuels to generate power. Thus, it may be useful to provide a solar-based system which can be used in a portable manner. Alternatively, it may be useful to provide a solar-based system which can be easily installed in an essentially permanent fashion.

One aspect of networked power supply is that the network can be monitored and problems can be located relatively quickly. When a solar system is isolated from the electrical grid, monitoring through the electrical grid necessarily ends. Thus, it may also be useful to provide a solar-based system which can be monitored remotely.

### BRIEF DESCRIPTION OF THE DRAWINGS

The present invention is illustrated by way of example in the accompanying drawings. The drawings should be understood as illustrative rather than limiting.

FIG. 1 illustrates an embodiment of a free standing solar power supply.

FIG. 2 illustrates an embodiment of a network of free standing power supplies.

FIG. 3 illustrates an embodiment of a free standing power supply.

FIG. 4 illustrates an embodiment of a process of controlling power supply from a free standing power supply.

FIG. 5 illustrates an embodiment of a process of monitoring and controlling a free standing power supply.

FIG. 6 illustrates an embodiment of a process of remotely monitoring a free standing power supply.

FIG. 7 illustrates an embodiment of a network which may be used with a free standing power supply.

FIG. 8 illustrates an embodiment of a machine which may be used with a free standing power supply.

FIG. 9 illustrates an embodiment of a system using free standing solar power supplies.

FIG. 10 illustrates another embodiment of a free standing power supply.

### DETAILED DESCRIPTION

A system, method and apparatus is provided for a solar power supply with monitoring and communications. The specific embodiments described in this document represent exemplary instances of the present invention, and are illustrative in nature rather than restrictive.

In the following description, for purposes of explanation, numerous specific details are set forth in order to provide a thorough understanding of the invention. It will be apparent, however, to one skilled in the art that the invention can be practiced without these specific details. In other instances, structures and devices are shown in block diagram form in order to avoid obscuring the invention.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment, nor are separate or alternative embodiments mutually exclusive of other embodiments. Features and aspects of various embodiments may be integrated into other embodiments, and embodiments illustrated in this document may be implemented without all of the features or aspects illustrated or described.

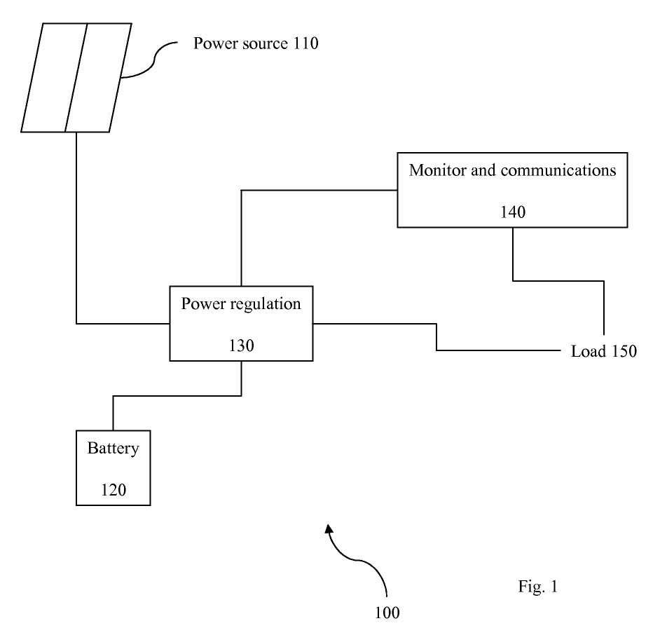

FIG. 1 illustrates an embodiment of a free standing solar power supply. Power supply 100 includes a solar module, battery, power regulator and a monitor module, all of which operate to supply a load. Solar module 110 may be any of a number of solar modules, such as those available from Sharp or General Electric, for example. Solar module 110 produces electricity by converting solar energy into an electrical current. Battery 120, may similarly be any number of different types of batteries, typically depending on electrochemical reactions to store and release power. Depending on the type of load expected, various different types of batteries may be preferable. For example, batteries that handle power surges may be more important with some loads, and batteries with long sustained current output may be more important with other loads.

Coupled to both battery 120 and solar module 110 is power regulation module 130. Power regulation module 130 may be any number of different types of charge controllers or power supplies, depending on the type of load anticipated. In particular, power regulation module 130 may be implemented as an MPPT (Maximum Power Point Tracking) module, such as those available from Blue Sky Energy of Vista, Calif. Module 130 may regulate incoming power from solar module 110, smoothing out some spikes or troughs in power output for example, and converting the output to a more regular voltage and current, as necessary.

Moreover, module 130 may monitor power output of solar module 110, determining if enough, too much or too little power is being generated. If too much power, module 130 may charge battery 120 if possible or dissipate the excess power while supplying load 150. If enough power, module 130 may simply supply load 150 with power. If too little power, module 130 may actively draw power from battery 120 to supplement solar module 110 and thereby deliver adequate power to load 150. Also, as required, module 130 may simply draw all power from battery 120 to supply load 150.

Module 130 may further provide outputs in the form of data or signals useful for telemetry and monitoring purposes in some embodiments. This may come in the form of a few dedicated signals, such as a loss of power signal and an oversupply signal, for example. Alternatively, it may implemented in the form of a set of data lines which communicate a wide range of information in an encoded form, for example.

Coupled to power regulation module 130 is monitoring module 140. Module 140 may be implemented in a custom, semi-custom or generic manner, for example. Thus, module 140 may be implemented through use of monitoring software available from Fat Spaniel Technologies of San Jose, Calif. executed by an embedded processor or associated hardware, for example. Alternately, a custom implementation may be provided.

Monitoring module 140 monitors power regulation module 130, and may directly monitor solar module 110 and/or battery 120 (not shown). Monitoring module 140 measures output or input of the various modules, either directly or through readings available from regulation module 130. Based on these readings, monitoring module 140 determines whether the system 100 is operating within predetermined specifications. If so, monitoring module 140 may periodically report status and operating history (a series of measurements for example) to an external control location. If the system 100 is not operating properly, monitoring module 140 may report this to an external control location, and also take immediate action locally. Thus, module 140 may signal an expected or imminent shutdown to the load 150. Additionally, module 140 may act to shut down power regulation module 130, or to modify activity of regulation module 130, such as stopping or starting charging of battery 120, or switching to battery 120 for power, for example. Also, module 140 may receive commands from a remote controller (not shown) which may cause module 140 to modify operation of system 100.

Thus, system 100 may collect power by converting received sunlight to electrical power using solar module 110. That power may then be stored in battery 120 or supplied to load 150. The process may be controlled at an instantaneous level by power regulation module 130 and may be monitored and controlled by monitoring module 140.

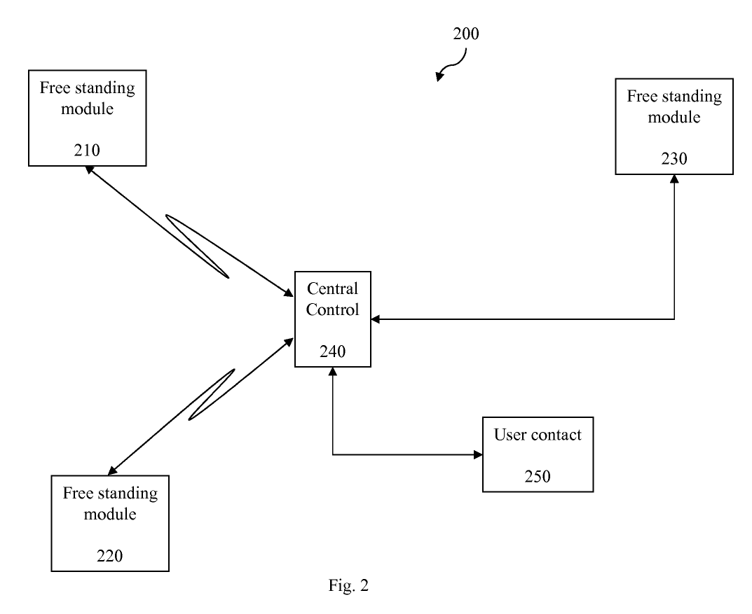

A free standing module may supply power in isolation to a device or system. Alternately, a free standing module may be part of an overall network of equipment. Such a network need not by physically connected, but some form of monitoring and control may be desirable. FIG. 2 illustrates an embodiment of a network of free standing power supplies.

Network 200 includes a set of free standing power supply modules and a central control system. Thus, free standing power module 210 may be a power supply for a first remote system, such as a charging station in a remote part of a facility. Similarly, free standing power module 220 may be a power supply for a second remote system, such as a relatively remote installation. Free standing power module 230 may be a power supply for a third remote system. Module 230 may provide emergency power supply to a system which is physically close to central control 240, but is intended to be isolated for purposes of avoiding interference from a failing power grid in an emergency—such as a system for powering emergency doors and lighting, for example.

Central control module 240 is coupled to each of modules 210, 220 and 230. As illustrated, modules 210 and 220 are coupled through radio frequency links, rather than physical couplings, while module 230 is coupled more directly (such as through a cable or other physical link) to control module 240. Central control module 240 may then perform a number of functions. For example, it may generally monitor status of the modules 210, 220 and 230, such as by receiving telemetry or status reports.

Note that communication links of an indirect form may take a wide variety of forms. For example, radio-frequency links through technologies using standards such as Bluetooth or IEEE 802.11 may be used. Alternatively, indirect connection may be achieved through use of access to a cellular network or a wired connection to a network. In either instance, a dedicated connection may be used (e.g. dialing a specific phone number through a cellular network or attaching to a dedicated, private wired network). Alternatively, access through other publicly accessible or semi-public networks may be used, such as through transmission of information through an internet service provider and through the internet to control module 240.

Moreover, central control module 240 may receive communications of exceptions from modules 210, 220 and 230, with information provided in such communications serving to indicate failures or warnings, for example. Additionally, central control module 240 can periodically ping or request information from modules 210, 220 and 230, thereby not only receiving information but receiving confirmation of continued operation based on the received response. Should an exception occur, either one communicated or one recognized from a communication failure, central control module 240 can then act to notify a user through user contact module 250. User contact module 250 may represent a user interface physically coupled to central control module 240 (e.g. a display) or may represent a communications path to a user, such as a dialer and modem for transfer of data to a remote user device such as a computer or communications device, for example.

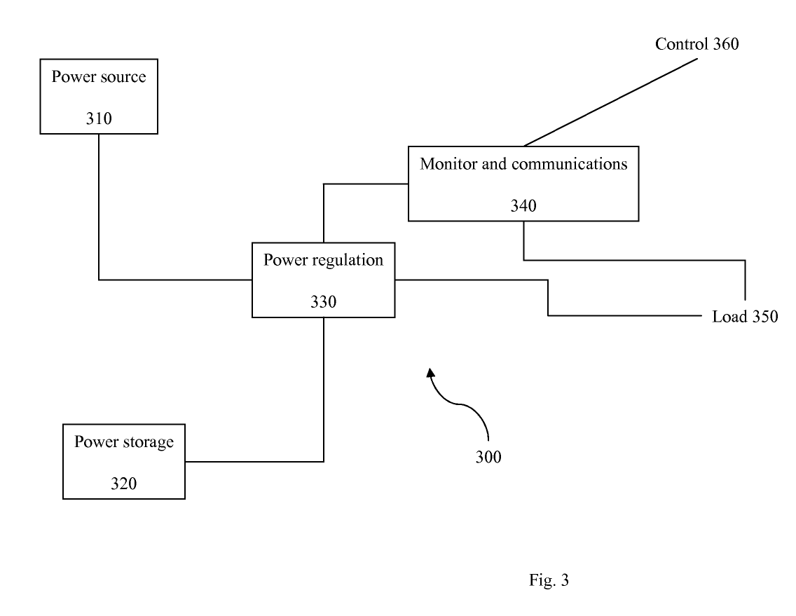

The discussion so far has focused on solar power. However, other generation options exist. FIG. 3 illustrates an embodiment of a free standing power supply. Power supply 300 includes a power source, power storage module, power regulator and a monitor module, all of which operate to supply a load, and may operate with an external control module as well. Power source 310 may be a solar module, a wind turbine, a geothermal conversion module or other power generation source, for example. Power source 310 produces electricity by converting some other form of energy into an electrical current. Power storage module 320, may similarly be any number of different types of power storage modules, such as batteries, capacitive arrays, flywheels, or other power storage modules. Depending on the type of load expected, various different types of power storage modules may be preferable. For example, power storage modules with long sustained current output may be more important with some loads, and power storage modules that handle power surges may be more important with other loads.

Coupled to both power source 310 and power storage module 320 is power regulation module 330. Power regulation module 330 may be any number of different types of charge controllers or power supplies, depending on the type of load anticipated. In particular, power regulation module 330 may be implemented as an MPPT or similar power monitoring and regulating module. Module 330 may regulate incoming power from power source 310, smoothing out some spikes or troughs in power output for example, and converting the output to a desired voltage and current, as necessary. Some power regulation modules may provide AC to DC conversion, or stepping of DC or AC power, for example.

Also, module 330 may monitor power output of power source 310, determining if too little, enough, or too much power is being generated. If too little power, module 330 may actively draw power from power storage module 320 to supplement power source 310 and thereby deliver adequate power to load 350. If enough power, module 330 may simply supply load 350 with power. If too much power, module 330 may store power at power storage module 320 if possible or dissipate the excess power while supplying load 350. Also, as required, module 330 may simply draw all power from power storage module 320 to supply load 350. Moreover, module 330 may provide signals or some form of indication that various events have occurred, such as a loss of power supply, sustained decrease in power output, or an oversupply condition, for example.

Coupled to power regulation module 330 is monitoring module 340. Module 340 may be implemented in a custom, semi-custom or generic manner, for example. Monitoring module 340 monitors power regulation module 330, and may directly monitor power source 310 and/or power storage module 320 (not shown).

Monitoring module 340 measures output or input of the various modules, either directly or through readings available from regulation module 330. Based on these readings, monitoring module 340 determines whether the system 300 is operating within preset specifications. If so, monitoring module 340 may periodically report status and operating history (a series of measurements for example) to an external system such as control system 360.

If the system 300 is not operating properly, monitoring module 340 may report this to a control system 360, and also take immediate action locally. Thus, module 340 may signal an expected or imminent shutdown to the load 350. Additionally, module 340 may act to shut down power regulation module 330, or to modify activity of regulation module 330, such as stopping or starting charging of battery 320, or switching to battery 320 for power, for example. Also, module 340 may receive commands from control system 360 which may cause module 340 to modify operation of system 300. Other applications of module 340 may similarly be used in the system or in conjunction with a load or an external control. Also, module 340 may operate in part by receiving notification signals from module 330, or may detect conditions simply by monitoring power output from module 330.

Thus, system 300 may collect power by converting received sunlight to electrical power using power source 310. That power may then be stored in power storage module 320 or supplied to load 350. The process may be controlled at an instantaneous level by power regulation module 330 and may be monitored and controlled by monitoring module 340 locally and by control system 360 remotely.

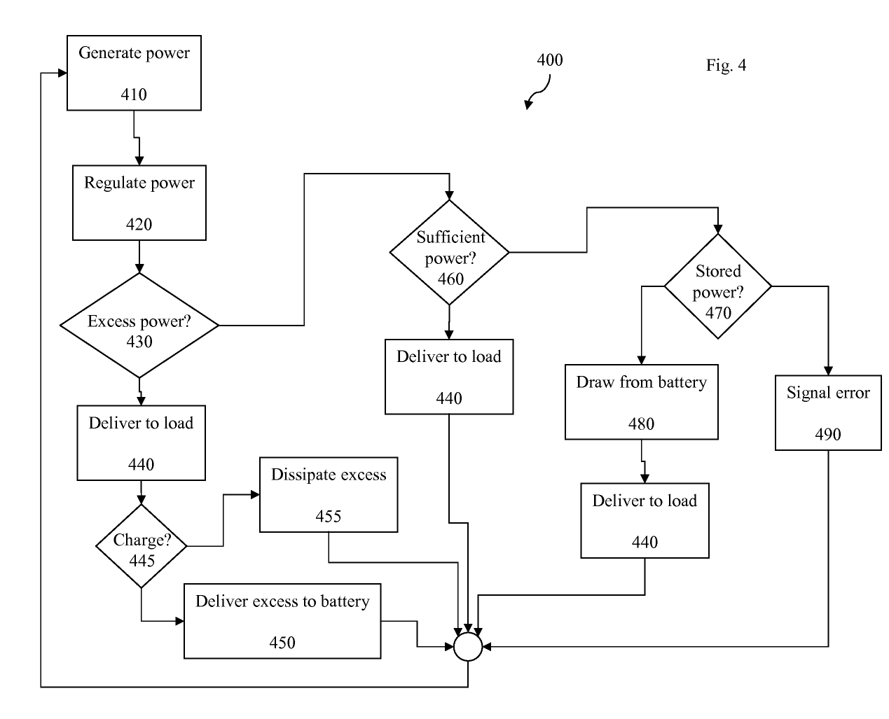

Various processes may be implemented to regulate power in systems such as system 100 and system 300, for example. FIG. 4 illustrates an embodiment of a process of controlling power supply from a free standing power supply. Method 400 and other methods of this document are composed of modules which may be rearranged into parallel or serial configurations, and may be subdivided or combined. The method may include additional or different modules, and the modules may be reorganized to achieve the same result, too. Process 400 includes generating power, regulating the power instantaneously (smoothing), determining if excess or sufficient power is available, delivering power to a load, determining if a battery may be charged or needs to be drawn from, and either charging or drawing from a battery.

Process 400 may be understood with reference to module 410, where power is generated, or received from a source. The received power is regulated at module 420, such as by smoothing the power from an oversupply or undersupply condition. At module 430, a determination is made as to whether excess power is available. If so, power is delivered to a load at module 440. Moreover, a determination is made at module 445 as to whether a battery or power storage module may be charged. If so, the excess power is delivered to the battery at module 450, preferably in a fashion (e.g. trickle charge or high power charge) appropriate for the battery at that time. If the battery is at capacity, power may be dissipated at module 455 to handle the excess power.

If there is no excess power, at module 460 a determination is made as to whether sufficient power is available. If so, then power is delivered at module 440. If not, a determination is made at module 470 as to whether stored power is available. If so, power is drawn from a battery or power storage module at module 480, and delivered to a load at module 440. If stored power is not available, then at module 490 an error is signaled. The process continues under most circumstances with generation or receipt to more power at module 410, excepting the situation where no power is available and an underlying system shuts down.

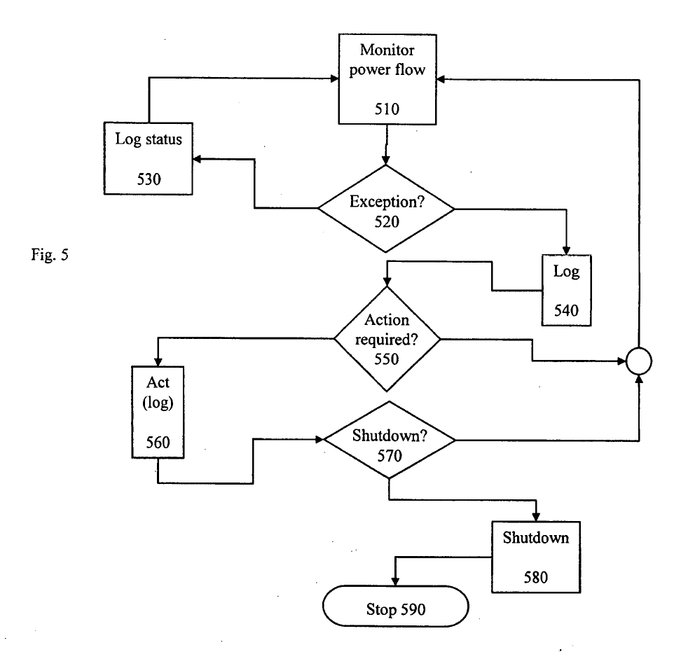

While the power management process may be handled to simply supply a load, a monitoring process may be used for additional functions. FIG. 5 illustrates an embodiment of a process of monitoring and controlling a free standing power supply. Process 500 includes monitoring power flow, determining if an exception has occurred, logging status data and logging exceptions, determining if an action is required, performing an action, determining if the system needs to shutdown, and shutting down the system if necessary.

Process 500 operates by monitoring power flow at module 510 such as by receiving measurements of operating parameters in the system on an ongoing basis. At module 520, a determination occurs as to whether an exception has arisen. An exception may be an indication that the system is operating outside of specifications for parameters, that a signal of an exception has been received, that a periodic reporting timer has expired, or that a command from an external source has been received, for example. If no exception, status of the system is logged at module 530, such as by recording recent measurements in a machine-readable medium, and monitoring at module 510 continues.

If an exception has arisen, at module 540 the exception is logged, and at module 550, a determination is made as to whether action is required. If no action is required, monitoring continues at module 510. If action is required, the action is taken at module 560 and logged. This may involve looking up an action corresponding to a given exception condition, or there may be a single default action for all conditions. Thus, an action may include reporting an exception to an external controller, signaling an alarm, sending instructions to a power regulator, signaling a problem to a load, or some other form of action.

Additionally, a determination is made at module 570 as to whether the system needs to shut down. If no, monitoring continues at module 510. If yes (such as due to power supply loss or an external command), then the system is shut down or powered off at module 580. The process then terminates at termination module 590, until it is restarted at module 510.

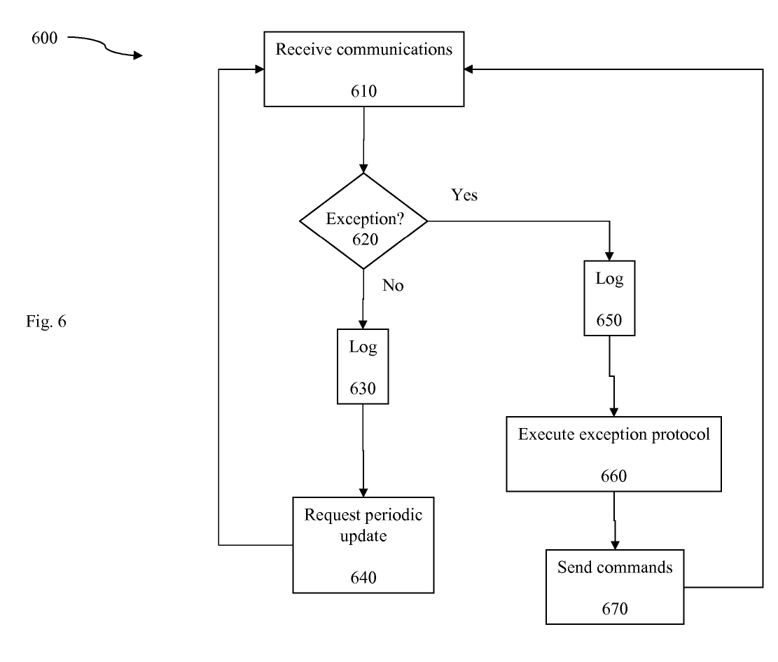

Local operations of a free standing power supply may also be monitored and controlled remotely. FIG. 6 illustrates an embodiment of a process of remotely monitoring a free standing power supply. Process 600 includes receiving communications, determining if an exception has occurred, logging the communications, requesting periodic updates, logging exceptions, executing exception protocol(s), and sending commands related to an exception as needed.

In general communications are received at module 610 on a periodic basis, except when exceptions occur. At module 620, a determination is made as to whether an exception has occurred. If no exception occurred, an incoming communication is logged and data stored at module 630 (along with update of any relevant displays). At module 640, the next periodic update is requested.

If an exception occurs, different processing then results. An exception may be a result of abnormal operation by the free standing power module, or as a result of a user command to change operation of the free standing power module. An exception is logged at module 650. At module 660, an appropriate protocol for the exception in question is found and followed. Thus, a user command may invoke a protocol to prepare commands for the free standing power module, whereas an error signal from the free standing power module may invoke a protocol to signal a user about the situation. Commands are sent to the free standing module, and any other system, at module 670. The system then returns to awaiting and receiving data at module 610.

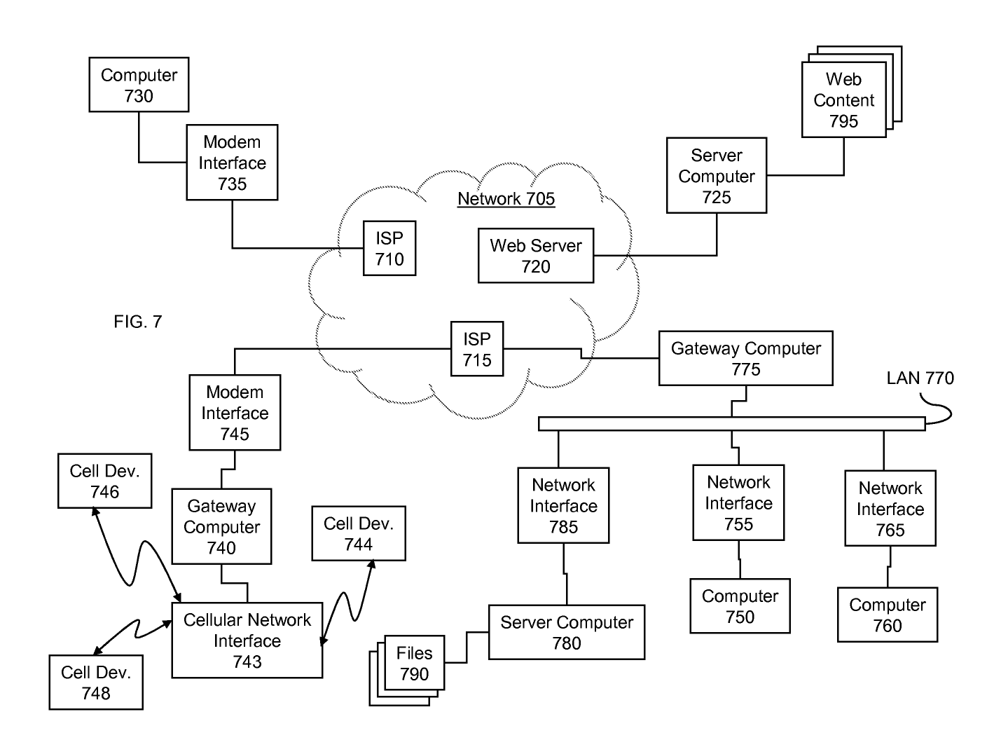

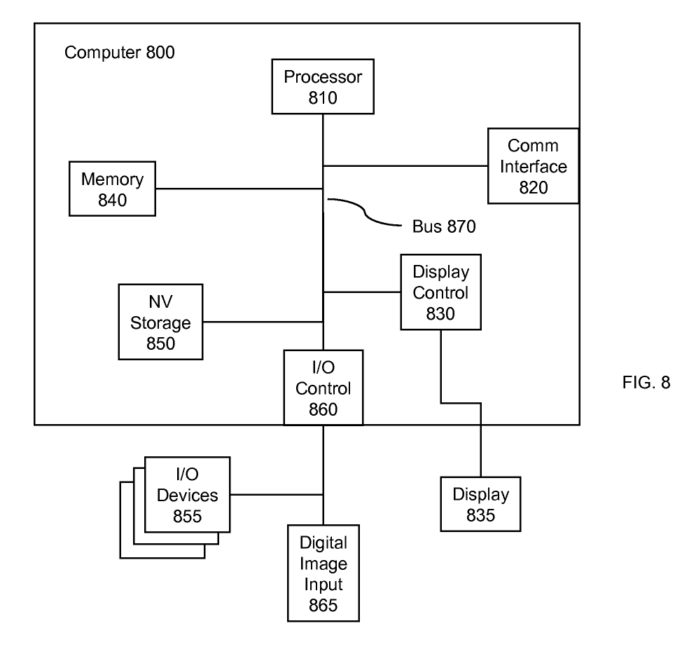

The following description of FIGS. 7-8 is intended to provide an overview of device hardware and other operating components suitable for performing the methods of the invention described above and hereafter, but is not intended to limit the applicable environments. Similarly, the hardware and other operating components may be suitable as part of the apparatuses described above. The invention can be practiced with other system configurations, including personal computers, multiprocessor systems, microprocessor-based or programmable consumer electronics, network PCs, minicomputers, mainframe computers, and the like. The invention can also be practiced in distributed computing environments where tasks are performed by remote processing devices that are linked through a communications network.

FIG. 7 shows several computer systems that are coupled together through a network 705, such as the internet, along with a cellular network and related cellular devices. The term “internet” as used herein refers to a network of networks which uses certain protocols, such as the TCP/IP protocol, and possibly other protocols such as the hypertext transfer protocol (HTTP) for hypertext markup language (HTML) documents that make up the world wide web (web). The physical connections of the internet and the protocols and communication procedures of the internet are well known to those of skill in the art.

Access to the internet 705 is typically provided by internet service providers (ISP), such as the ISPs 710 and 715. Users on client systems, such as client computer systems 730, 750, and 760 obtain access to the internet through the internet service providers, such as ISPs 710 and 715. Access to the internet allows users of the client computer systems to exchange information, receive and send e-mails, and view documents, such as documents which have been prepared in the HTML format. These documents are often provided by web servers, such as web server 720 which is considered to be “on” the internet. Often these web servers are provided by the ISPs, such as ISP 710, although a computer system can be set up and connected to the internet without that system also being an ISP.

The web server 720 is typically at least one computer system which operates as a server computer system and is configured to operate with the protocols of the world wide web and is coupled to the internet. Optionally, the web server 720 can be part of an ISP which provides access to the internet for client systems. The web server 720 is shown coupled to the server computer system 725 which itself is coupled to web content 795, which can be considered a form of a media database. While two computer systems 720 and 725 are shown in FIG. 7, the web server system 720 and the server computer system 725 can be one computer system having different software components providing the web server functionality and the server functionality provided by the server computer system 725 which will be described further below.

Cellular network interface 743 provides an interface between a cellular network and corresponding cellular devices 744, 746 and 748 on one side, and network 705 on the other side. Thus cellular devices 744, 746 and 748, which may be personal devices including cellular telephones, two-way pagers, personal digital assistants or other similar devices, may connect with network 705 and exchange information such as email, content, or HTTP-formatted data, for example. Alternately, cellular devices 744, 746 and 748 may be communications components of remote systems, such as free standing power supplies, which may send and receive status and reporting data, and may also send and receive commands through the cellular network.

Cellular network interface 743 is representative of wireless networking in general. In various embodiments, such an interface may also be implemented as a wireless interface such as a Bluetooth interface, IEEE 802.11 interface, or some other form of wireless network. Similarly, devices such as devices 744, 746 and 748 may be implemented to communicate via the Bluetooth or 802.11 protocols, for example. Other dedicated wireless networks may also be implemented in a similar fashion.

Cellular network interface 743 is coupled to computer 740, which communicates with network 705 through modem interface 745. Computer 740 may be a personal computer, server computer or the like, and serves as a gateway. Thus, computer 740 may be similar to client computers 750 and 760 or to gateway computer 775, for example. Software or content may then be uploaded or downloaded through the connection provided by interface 743, computer 740 and modem 745.

Client computer systems 730, 750, and 760 can each, with the appropriate web browsing software, view HTML pages provided by the web server 720. The ISP 710 provides internet connectivity to the client computer system 730 through the modem interface 735 which can be considered part of the client computer system 730. The client computer system can be a personal computer system, a network computer, a web tv system, or other such computer system.

Similarly, the ISP 715 provides internet connectivity for client systems 750 and 760, although as shown in FIG. 7, the connections are not the same as for more directly connected computer systems. Client computer systems 750 and 760 are part of a LAN coupled through a gateway computer 775. While FIG. 7 shows the interfaces 735 and 745 as generically as a “modem,” each of these interfaces can be an analog modem, isdn modem, cable modem, satellite transmission interface (e.g. “direct PC”), or other interfaces for coupling a computer system to other computer systems.

Client computer systems 750 and 760 are coupled to a LAN 770 through network interfaces 755 and 765, which can be ethernet network or other network interfaces. The LAN 770 is also coupled to a gateway computer system 775 which can provide firewall and other internet related services for the local area network. This gateway computer system 775 is coupled to the ISP 715 to provide internet connectivity to the client computer systems 750 and 760. The gateway computer system 775 can be a conventional server computer system. Also, the web server system 720 can be a conventional server computer system.

Alternatively, a server computer system 780 can be directly coupled to the LAN 770 through a network interface 785 to provide files 790 and other services to the clients 750, 760, without the need to connect to the internet through the gateway system 775.

FIG. 8 shows one example of a personal device that can be used as a cellular telephone (744, 746 or 748) or similar personal device, or may be used as a more conventional personal computer, as an embedded processor or local console, or as a PDA, for example. Such a device can be used to perform many functions depending on implementation, such as monitoring functions, user interface functions, telephone communications, two-way pager communications, personal organizing, or similar functions. The system 800 of FIG. 8 may also be used to implement other devices such as a personal computer, network computer, or other similar systems. The computer system 800 interfaces to external systems through the communications interface 820. In a cellular telephone, this interface is typically a radio interface for communication with a cellular network, and may also include some form of cabled interface for use with an immediately available personal computer. In a two-way pager, the communications interface 820 is typically a radio interface for communication with a data transmission network, but may similarly include a cabled or cradled interface as well. In a personal digital assistant, communications interface 820 typically includes a cradled or cabled interface, and may also include some form of radio interface such as a Bluetooth or 802.11 interface, or a cellular radio interface for example.

The computer system 800 includes a processor 810, which can be a conventional microprocessor such as an Intel pentium microprocessor or Motorola power PC microprocessor, a Texas Instruments digital signal processor, or some combination of the two types or processors. Memory 840 is coupled to the processor 810 by a bus 870. Memory 840 can be dynamic random access memory (dram) and can also include static ram (sram), or may include FLASH EEPROM, too. The bus 870 couples the processor 810 to the memory 840, also to non-volatile storage 850, to display controller 830, and to the input/output (I/O) controller 860. Note that the display controller 830 and I/O controller 860 may be integrated together, and the display may also provide input.

The display controller 830 controls in the conventional manner a display on a display device 835 which typically is a liquid crystal display (LCD) or similar flat-panel, small form factor display. The input/output devices 855 can include a keyboard, or stylus and touch-screen, and may sometimes be extended to include disk drives, printers, a scanner, and other input and output devices, including a mouse or other pointing device. The display controller 830 and the I/O controller 860 can be implemented with conventional well known technology. A digital image input device 865 can be a digital camera which is coupled to an I/O controller 860 in order to allow images from the digital camera to be input into the device 800.

The non-volatile storage 850 is often a FLASH memory or read-only memory, or some combination of the two. A magnetic hard disk, an optical disk, or another form of storage for large amounts of data may also be used in some embodiments, though the form factors for such devices typically preclude installation as a permanent component of the device 800. Rather, a mass storage device on another computer is typically used in conjunction with the more limited storage of the device 800. Some of this data is often written, by a direct memory access process, into memory 840 during execution of software in the device 800. One of skill in the art will immediately recognize that the terms “machine-readable medium” or “computer-readable medium” includes any type of storage device that is accessible by the processor 810 and also encompasses a carrier wave that encodes a data signal.

The device 800 is one example of many possible devices which have different architectures. For example, devices based on an Intel microprocessor often have multiple buses, one of which can be an input/output (I/O) bus for the peripherals and one that directly connects the processor 810 and the memory 840 (often referred to as a memory bus). The buses are connected together through bridge components that perform any necessary translation due to differing bus protocols.

In addition, the device 800 is controlled by operating system software which includes a file management system, such as a disk operating system, which is part of the operating system software. One example of an operating system software with its associated file management system software is the family of operating systems known as Windows CE™ and Windows® from Microsoft Corporation of Redmond, Wash., and their associated file management systems. Another example of an operating system software with its associated file management system software is the Palm® operating system and its associated file management system. The file management system is typically stored in the non-volatile storage 850 and causes the processor 810 to execute the various acts required by the operating system to input and output data and to store data in memory, including storing files on the non-volatile storage 850. Other operating systems may be provided by makers of devices, and those operating systems typically will have device-specific features which are not part of similar operating systems on similar devices. Similarly, WinCE™ or Palm® operating systems may be adapted to specific devices for specific device capabilities.

Device 800 may be integrated onto a single chip or set of chips in some embodiments, and typically is fitted into a small form factor for use as a personal device. Thus, it is not uncommon for a processor, bus, onboard memory, and display/I-O controllers to all be integrated onto a single chip. Alternatively, functions may be split into several chips with point-to-point interconnection, causing the bus to be logically apparent but not physically obvious from inspection of either the actual device or related schematics.

Some portions of the detailed description are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussion, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

The present invention, in some embodiments, also relates to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, and each coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description below. In addition, the present invention is not described with reference to any particular programming language, and various embodiments may thus be implemented using a variety of programming languages.

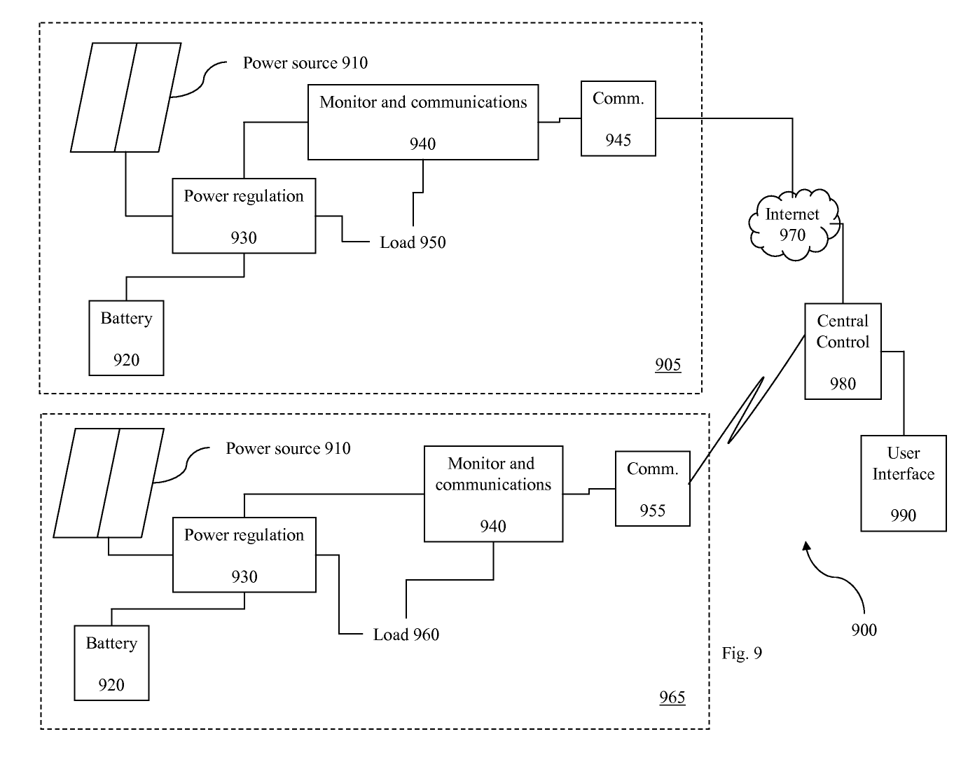

Other examples of free standing power supplies may involve variations of embodiments previously described and illustrated. FIG. 9 illustrates an embodiment of a system using free standing solar power supplies. System 900 includes two free standing power supplies, a central control module, and communications links therebetween. Solar modules 910 may be any of a number of solar modules, such as those available from Sharp or General Electric, for example. Batteries 920, may similarly be any number of different types of batteries, typically depending on electrochemical reactions to store and release power.

Coupled to each of batteries 920 and solar modules 910 are power regulation modules 930. Power regulation modules 930 may be any number of different types of charge controllers or power supplies, depending on the type of load anticipated. In particular, power regulation modules 930 may be implemented as MPPT (Maximum Power Point Tracking) modules, such as those available from Blue Sky Energy of Vista, Calif. Modules 930 may regulate incoming power from solar modules 910, and supply power to loads 950 and 960, while either charging or drawing power from batteries 920.

Modules 930 may further provide outputs in the form of data or signals useful for telemetry and monitoring purposes in some embodiments. This (data output) may come in the form of a few dedicated signals, such as a loss of power signal and an oversupply signal, for example. Alternatively, data output may implemented in the form of a set of data lines which communicate a wide range of information in an encoded form, for example.

Coupled to power regulation module 930 is monitoring module 940. Module 940 may be implemented in a custom, semi-custom or generic manner, for example. Thus, module 940 may be implemented through use of monitoring software available from Fat Spaniel Technologies of San Jose, Calif. executed by an embedded processor or associated hardware, for example. Alternately, a custom implementation may be provided.

Monitoring module 940 monitors power regulation modules 930, and may directly monitor solar modules 910 and/or batteries 920 (not shown). Monitoring modules 940 measure output or input of the various modules, either directly or through readings available from regulation module 930. Based on these readings, each monitoring module 940 determines whether the free standing power supply is operating within predetermined specifications. If so, each monitoring module 940 may periodically report status and operating history (a series of measurements for example) to central control 980. If the power supply is not operating properly, monitoring modules 940 may report this to central control 980, and also take immediate action locally.

Each of power supplies 905 and 965 use different communication methodologies. Illustrated as separate components are communications modules 945 and 955. Communications module 945 may be a modem or similar device which can connect to the internet 970, such as through a dedicated ISP connection, for example. Communications module 955 may be a wireless communications module such as a cellular communications module, a Bluetooth communications module or an IEEE 802.11-based communications module, for example. Thus, each communications module (945 and 955) provides a connection to central control 980, for central monitoring and commands. Moreover, central control 980 further provides a user interface 990, allowing for user control at a central location, away from the locations of the systems 905 and 965.

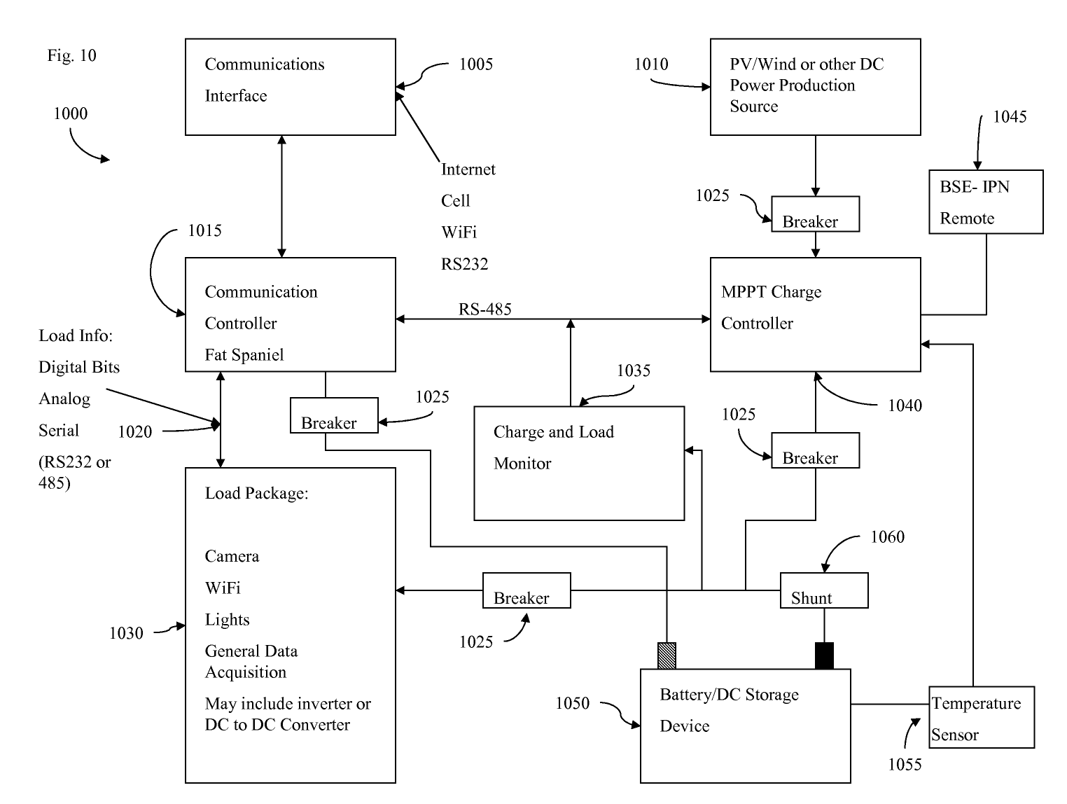

A more detailed explanation of some of the components of a free standing power supply may be useful. FIG. 10 illustrates another embodiment of a free standing power supply. System 1000 provides a communications interface, communications controller, power supply, power supply controller, charge monitor, battery, a load, and associated breakers and related components.

Power is generated by power supply 1010, a power source such as a solar module, wind turbine or other power source for example. Power source 1010 is coupled to MPPT charge controller 1040 through a breaker 1025, allowing for near optimal power generation. Remote 1045 allows for local monitoring in a slightly remote location through a local radio or infrared interface, for example. MPPT 1040 is coupled through another breaker 1025 to shunt 1060 and thereby to battery 1050 (at both terminals). This two-terminal connection is also made to charge and load monitor 1035, and through breakers 1025 to Fat Spaniel communication controller 1015 and load 1030.

MPPT 1040 monitors temperature sensor 1055, which senses temperature data for battery 1050 to provide near optimal charge flow to battery 1050. Similarly, controller 1015 monitors battery 1050 and load 1030 (through data bus 1020) to determine performance of the system. Additionally, monitor 1035 provides further feedback information about the over all system. Controller 1015, MPPT 1040 and monitor 1035 each communicate via a local bus, illustrated as an RS 485 bus, but implementable in other ways as well. Additionally, communications interface 1005 allows controller 1015 to communicate with a remote system, through wired or wireless communications protocols and facilities. This, in turn, allows for a remote controller to monitor the system 1000 and to provide commands as necessary.

Thus, system 1000 can potentially provide a number of advantages, which may be realized with other similar implementations, including those of FIGS. 1, 3 and 9, for example. The system 1000 may be a web-enabled system, allowing for access through communications module 1005, or may operate as a networked device. Thus, it may be a standalone power supply or may operate in a standalone manner as part of a multi-point or redundant power supply system. Additionally, with the components described, system 1000 and similar systems may have a relatively small footprint. Moreover, the MPPT modules available from Blue Sky Energy have been shown to potentially increase solar module output by as much as 25% over standard power regulation modules, allowing for better performance and better environmental impact. Likewise, the low number of components involved in system 1000 potentially reduces manufacturing costs and environmental impact, and may allow for a more aesthetic package.

Various implementations of free standing power supply modules can take advantage of some or all of the features of the embodiments described above. The free standing power supply modules may be used in a variety of applications. For example, a cell telephone antenna may be powered with a free standing power supply module, allowing for location of such antennas without regard to availability of power. Moreover, charging stations may be provided through use of such free standing power supply modules, allowing for charging of batteries in remote locations or in areas where grid-based electricity is difficult to provide. Thus, a harbor may provide charging facilities for boats and ships without running power cables out along docks and slips.

Additionally, a free standing power supply module may be made in a portable form factor, and used with recreational vehicles or in outdoor settings to supply power or charge batteries for people visiting remote locations. Also, a free standing power supply module may be used to provide power to lights for locations where power cables have not been supplied, such as in large parking lots or along roads. Likewise, as mentioned, a free standing power supply module may be used to power emergency equipment such as lights, power-assisted doors, and communications equipment, without requiring access to a potentially error-prone electrical grid.

Further applications for a free standing power supply may involve powering equipment for voice-over-internet protocol (VoIP) communications. Similarly, power may be supplied for emergency communications equipment, either of basic plain old telephone service (POTS) or of encrypted emergency communications, for example. Additionally, free standing power supplies may be used to provide video surveillance of remote areas by powering video equipment and related communications equipment. Moreover, WIFI transmission in general may be powered with a free standing power supply.

One skilled in the art will appreciate that although specific examples and embodiments of the system and methods have been described for purposes of illustration, various modifications can be made without deviating from the present invention. For example, embodiments of the present invention may be applied to many different types of databases, systems and application programs. Moreover, features of one embodiment may be incorporated into other embodiments, even where those features are not described together in a single embodiment within the present document.

What is claimed is:

1. That which is described and equivalents thereof.

2. Embodiments as described and illustrated, and combinations of features from separate embodiments.

3. An apparatus, comprising:
A power source;
A power regulation module coupled to the power source;
A battery coupled to the power regulation module; and
A communications module coupled to the power regulation module.

4. The apparatus of claim 3, wherein:
The power regulation module is an MPPT.

5. The apparatus of claim 3, wherein:
The power source is an array of solar cells.

6. A system comprising:
A central control module;
A central communications module coupled to the central control module;
A user interface coupled to the central control module;
A first remote power supply including:
A power source;
A power regulation module coupled to the power source;
A battery coupled to the power regulation module; and
A remote communications module coupled to the power regulation module;
Wherein the remote communications module of the first remote power supply is coupled to the central communications module.

7. The system of claim 6, further comprising:
A second remote power supply including:
A power source;
A power regulation module coupled to the power source;
A battery coupled to the power regulation module; and
A remote communications module coupled to the power regulation module;
Wherein the remote communications module of the second remote power supply is coupled to the central communications module.

8. A method, comprising:
Generating power;
Regulating the power;
Monitoring power; and
Delivering power to a load.

9. The method of claim 8, further comprising:
Storing power in a battery when excess power is generated.

10. The method of claim 8, further comprising:
Delivering power from a battery when excess power is demanded from the load.

11. The method of claim 8, further comprising:
Generating an error signal when excess power is demanded from the load and the battery is depleted.
